(19) United States
(12) Patent Application Publication
(10) Pub. No.: US 2026/0275707 A1
(43) Pub. Date: Sep. 17, 2026

(54) PROCESSING INFORMATION FORMING SYSTEM AND PROCESSING INFORMATION FORMING PROGRAM

(71) Applicant: SEKISUI HOUSE, LTD., Osaka-shi, Osaka (JP)

(72) Inventor: Kazuya TANIOKA, Osaka-shi (JP)

(21) Appl. No.: 19/161,943

(22) PCT Filed: Jan. 26, 2024
(86) PCT No.: PCT/JP2024/002469

§ 371 Date: Sep. 3, 2025

(30) Foreign Application Priority Data
Jul. 28, 2023 (JP) 2023-123069

(51) Int. Cl. E04B 1/26; G06F 30/13; G06F 30/20

(52) U.S. Cl. CPC E04B 1/2604; G06F 30/13; G06F 30/20; E04B 2001/2652

(57) ABSTRACT

An information acquisition unit of a processing information generation system acquires wooden structural member information, metal fitting information connected to the wooden structural member, and fixed position information of the metal fittings to the wooden structural member. A processing information generation unit of the processing information generation system groups ones of the metal fittings having overlapping hole positions in a height direction when the metal fittings are arranged on the wooden structural member. The grouping is based on the metal fitting information and the fixed position information. The processing information generation unit sets bolt hole candidates for fixing the metal fittings that belong to the group based on the metal fitting information for each of the metal fittings that belong to the group. The processing information generation unit selects a bolt hole that satisfies a fixing condition for the metal fittings from the bolt hole candidates.

### TECHNICAL FIELD

The present disclosure relates to a processing information generation system and a processing information generation program for wooden members in a building.

### BACKGROUND

For wooden buildings, it is known that processing data for wooden members is generated using a computational system. Patent Literature 1 discloses an example of technique in which master data is used to generate processing data for wooden members. In the technique disclosed in the literature, design data for metal fittings that are automatically modified based on the direction in which wooden members extend is generated. Further, processing data for wooden members to be joined to each other based on the design data for the automatically modified metal fittings is generated.

### CITATION LIST

### Patent Literature

Patent Literature 1: JP2018-156630A

### SUMMARY OF INVENTION

### Technical Problem

In buildings, multiple metal fittings may be connected to a wooden structural member, which serves as a structural component of the building. In such cases, the bolts used to fix the metal fittings to the wooden structural member are positioned such that the bolts in a wooden member do not interfere with each other. However, positioning the bolts in this manner is a labor-intensive task. Thus, there is room for improvement in terms of work efficiency in generating the processing data for the wooden structural member.

### Solution to Problem

(1) A processing information generation system that solves the above-described problem generates hole forming information for a wooden structural member. The processing information generation system includes an information acquisition unit and a processing information generation unit. The information acquisition unit acquires wooden structural member information, metal fitting information for metal fittings connected to the wooden structural member, and fixed position information indicating a position at which each of the metal fittings is fixed to the wooden structural member. The processing information generation unit executes a grouping process in which, when the metal fittings are arranged on the wooden structural member, ones of the metal fittings having overlapping hole positions are grouped in a height direction. The grouping is based on the metal fitting information and the fixed position information. The processing information generation unit executes a hole candidate setting process that sets, based on the metal fitting information for each of the metal fittings that belong to the group, bolt hole candidates for fixing the metal fittings that belong to the group. The processing information generation unit executes a selection process that selects a bolt hole that satisfies a fixing condition for the metal fittings from the bolt hole candidates.

Conventionally, hole positions are set for a wooden structural member without grouping metal fittings having overlapping bolt hole positions. For example, bolt holes are set in the order of metal fittings having a larger number of bolt holes. With this method of setting, the final metal fitting may not satisfy a condition for the metal fittings. This creates the need to review the bolt hole positions for all the metal fittings. In the above-described configuration, the grouping process is executed to group the metal fittings having overlapping bolt hole positions. This allows the hole positions to be determined for each group and thus minimizes the need to reset hole positions. In this manner, the efficiency of generating processing data for the wooden structural member is enhanced.
(2) In the processing information generation system according to (1), the wooden structural member includes a first side surface, a second side surface, a third side surface opposite the first side surface, and a fourth side surface opposite the second side surface. The processing information generation unit performs, in the grouping process, classifying ones of the grouped metal fittings arranged on the first side surface and the third side surface into a first subgroup and classifying ones of the grouped metal fittings arranged on the second side surface and the fourth side surface into a second subgroup. The processing information generation unit performs, in the hole candidate setting process, setting first bolt hole candidates for the first subgroup and second bolt hole candidates for the second subgroup. The processing information generation unit performs, in the selection process, selecting a bolt hole from each of the first bolt hole candidates and the second bolt hole candidates such that a bolt hole selected from the first bolt hole candidates and a bolt hole selected from the second bolt hole candidates do not interfere with each other and the fixing condition for the metal fittings is satisfied.

When bolt hole candidates are independently set for each of the metal fittings provided on the wooden structural member, the number of possible combinations for selecting non-interfering bolt holes increases, which may result in a more complicated calculation. In the above-described configuration, each of the first and second subgroups is formed by grouping the metal fittings located on the opposite sides of the wooden structural member. Further, candidates for the bolt holes are set independently for each of the first and second subgroups. This reduces the number of selectable bolt holes, thereby improving calculation efficiency.
(3) In the processing information generation system according to (1), the processing information generation unit performs, in the grouping process, creating a group by repeating a group association process on the metal fittings in an order in which the metal fittings are arranged in the height direction. The processing information generation unit performs, in the group association process, assigning a metal fitting subject to the grouping process to the group when a position of one of metal fitting holes of the metal fitting subject to the grouping process overlaps a position of a metal fitting hole of at least one of the metal fittings that have already been assigned to the group prior to the metal fitting subject to the grouping process.

Among multiple metal fittings, even two metal fittings that are spaced apart from each other in the height direction may belong to the same group together with other metal fittings, depending on their relationship with those other metal fittings. Accordingly, if grouping is performed based solely on the relationship between one reference metal fitting and other metal fittings, two metal fittings spaced apart from each other in the height direction may not belong to the same group. The above-described configuration prevents a metal fitting that should be grouped from being excluded from that group, thereby properly grouping metal fittings.
(4) In the processing information generation system according to (1), the processing information generation unit further executes a bolt hole type determination process. In the bolt hole type determination process, the processing information generation unit sets a type of bolt hole for each of the bolt hole candidates or each of the selected bolt holes based on a positional relationship between the metal fittings. This configuration allows the type of bolt hole to be set.
(5) In the processing information generation system according to (4), the wooden structural member includes a first side surface, a second side surface, a third side surface opposite the first side surface, and a fourth side surface opposite the second side surface. The processing information generation unit performs, in the grouping process, classifying ones of the grouped metal fittings arranged on the first side surface and the third side surface into a first subgroup and classifying ones of the grouped metal fittings arranged on the second side surface and the fourth side surface into a second subgroup The processing information generation unit performs, in the hole candidate setting process, setting first bolt hole candidates for the first subgroup and second bolt hole candidates for the second subgroup The processing information generation unit performs, in the selection process, selecting a bolt hole from each of the first bolt hole candidates and the second bolt hole candidates such that a bolt hole selected from the first bolt hole candidates and a bolt hole selected from the second bolt hole candidates do not interfere with each other and the fixing condition for the metal fittings is satisfied.

In the above-described configuration, each of the first and second subgroups is formed by grouping the metal fittings located on the opposite sides of the wooden structural member. Further, candidates for the bolt holes are set independently for each of the first and second subgroups. This reduces the number of selectable bolt holes, thereby improving calculation efficiency.
(6) In the processing information generation system according to (5), the processing information generation unit performs, in the grouping process, creating a group by repeating a group association process on the metal fittings in an order in which the metal fittings are arranged in the height direction. The processing information generation unit performs, in the group association process, assigning a metal fitting subject to the grouping process to the group when a position of one of metal fitting holes of the metal fitting subject to the grouping process overlaps a position of a metal fitting hole of at least one of the metal fittings that have already been assigned to the group prior to the metal fitting subject to the grouping process. The above-described configuration prevents a metal fitting that should be grouped from being excluded from that group, thereby properly grouping metal fittings.
(7) In the processing information generation system according to any one of (1) to (6), in the hole candidate setting process, the processing information generation unit selects the bolt hole candidates based on fixing hole information. The fixing hole information is included in the metal fitting information. This configuration allows for selection of bolt hole candidates suitable for each metal fitting.
(8) A processing information generation program that solves the above-described problem causes a computer to generate hole forming information for a wooden structural member. The processing information generation program includes an information acquisition step and a processing information generation step. The information acquisition step causes the computer to acquire wooden structural member information, metal fitting information for metal fittings connected to the wooden structural member, and fixed position information indicating a position at which each of the metal fittings is fixed to the wooden structural member. The processing information generation step causes the computer to execute a grouping process in which, when the metal fittings are arranged on the wooden structural member, ones of the metal fittings having overlapping hole positions are grouped in a height direction. The grouping is based on the metal fitting information and the fixed position information. The processing information generation step causes the computer to execute a hole candidate setting process that sets, based on the metal fitting information for each of the metal fittings that belong to the group, bolt hole candidates for fixing the metal fittings that belong to the group. The processing information generation step causes the computer to execute a selection process that selects a bolt hole that satisfies a fixing condition for the metal fittings from the bolt hole candidates.

In this configuration, the grouping process is executed to group metal fittings having overlapping hole positions. This allows the hole positions to be determined for each group and thus minimizes the need to reset hole positions. In this manner, the efficiency of generating processing data for the wooden structural member is enhanced.

### Advantageous Effects of Invention

The present disclosure enhances the efficiency of generating processing data for the wooden structural member.

### BRIEF DESCRIPTION OF DRAWINGS

FIG. 1 is a schematic view illustrating a framework of a wooden structural member.

FIG. 2 is a perspective view illustrating the wooden structural member to which metal fittings are connected.

FIG. 3 is a perspective view illustrating the metal fittings for the wooden structural member shown in FIG. 2.

FIG. 4 is a cross-sectional view illustrating the wooden structural member of FIG. 2 taken along line A-A.

FIG. 5 is a cross-sectional view illustrating the wooden structural member of FIG. 2 taken along line B-B.

FIG. 6 is a block diagram illustrating the processing information generation system.

FIG. 7 is a diagram illustrating a grouping process.

FIG. 8 is a diagram illustrating groups that are set for the wooden structural members.

FIG. 9 is a diagram illustrating first bolt hole candidates and types of bolt holes for a first subgroup.

FIG. 10 is a diagram illustrating second bolt hole candidates and types of bolt holes for the first subgroup.

FIG. 11 is a diagram illustrating the selection of bolt holes.

FIG. 12 is a diagram illustrating the selection of bolt holes and types of bolt holes.

FIG. 13 is a flowchart illustrating the processing executed by the processing information generation system.

### DESCRIPTION OF EMBODIMENTS

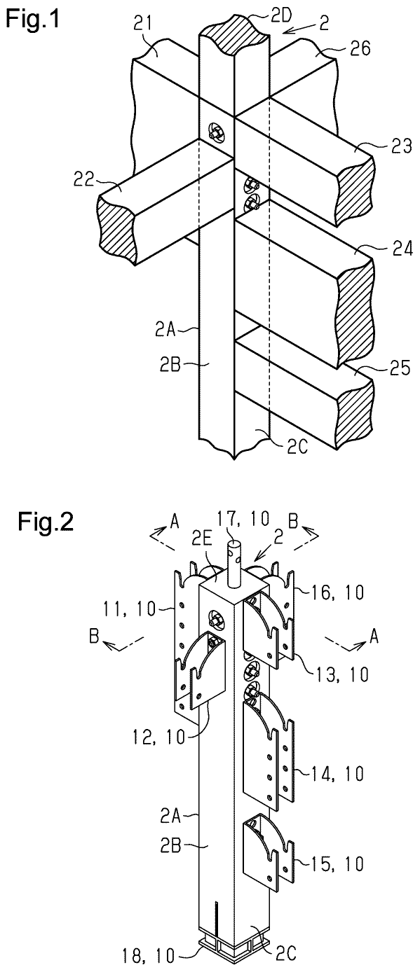

A processing information generation system 40 according to the present embodiment will now be described with reference to FIGS. 1 to 13.

As shown in FIGS. 1 and 2, a wooden structural member 2 is connected to several other structural members via metal fittings 10. The processing information generation system 40 performs calculation on the wooden structural member 2 to which the other structural members are connected via the metal fittings 10.

To generate hole forming information, the processing information generation system 40 acquires the information generated by a structural design system 1.

The structure of a building is designed by the structural design system 1, which is different from the processing information generation system 40. The processing information generation system 40 may be integrated in the structural design system 1. The structural design system 1 designs the structure of a building. The structural design system 1 sets the following items. The items set by the structural design system 1 include a framework structure composed of the wooden structural member 2 and horizontal members, the dimension of the wooden structural member 2, the dimensions of the horizontal members, the connection relationship at joint portions between the wooden structural member 2 and the horizontal members, and the types of metal fittings 10 provided on the wooden structural member 2.

The wooden structural member 2 is a structural component of a building. The wooden structural member 2 includes a column. In the present embodiment, the wooden structural member 2 does not include a stud. The wooden structural member 2 is coupled to other structural components using the metal fittings 10. The other structural components include a horizontal member and another wooden structural member 2. The other structural components may include a sloped transverse beam. Examples of the horizontal member include a transverse beam and a longitudinal beam. According to one definition, a longitudinal beam refers to a member that extends in the long-side direction as the building is viewed from above, while a transverse beam refers to a member that extends in the short-side direction and intersects the longitudinal beam. According to another definition, a longitudinal beam refers to a horizontal member that supports rafters, while a transverse beam refers to a member that does not support rafters and intersects the longitudinal beam. However, these definitions are not intended to be limiting.

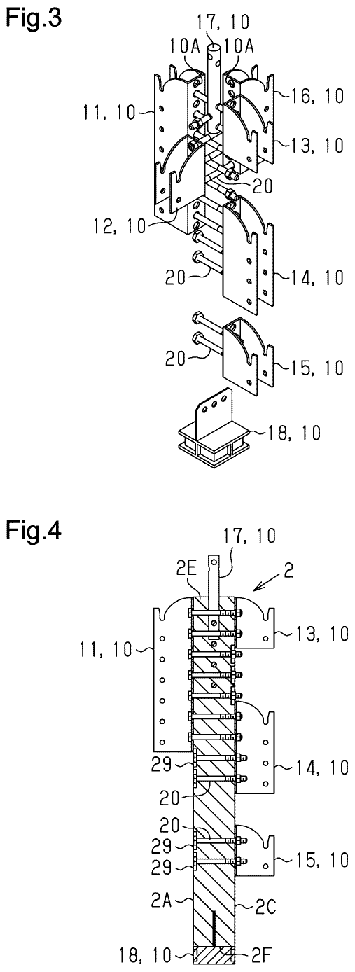

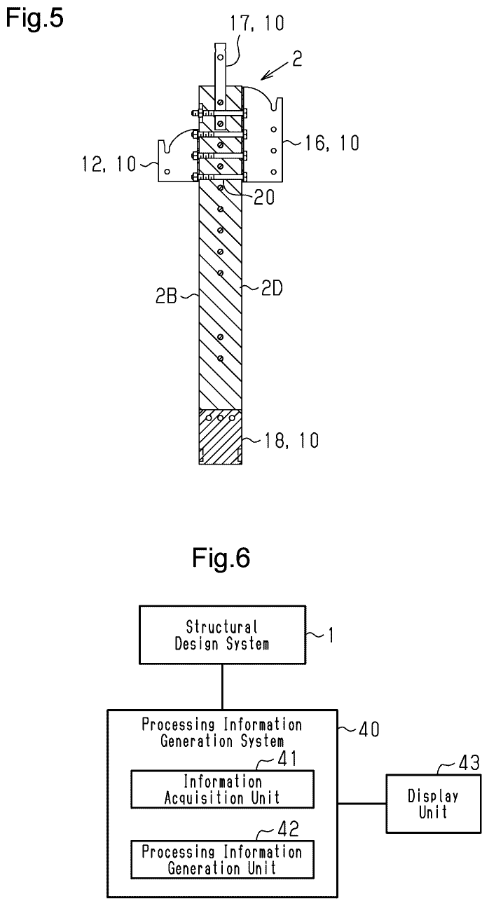

An example of the wooden structural member 2 will now be described with reference to FIGS. 2 to 5. The wooden structural member 2 shown in FIG. 2 is connected to a foundation. FIG. 3 illustrates a variation of FIG. 2 in which the wooden structural member 2 is not depicted. FIG. 4 is a cross-sectional view taken along line A-A of the wooden structural member 2 in FIG. 2. FIG. 5 is a cross-sectional view taken along line B-B of the wooden structural member 2 in FIG. 2.

A first metal fitting 11 used to connect a first horizontal member 21 to the wooden structural member 2 is connected to a first side surface 2A of the wooden structural member 2. A second metal fitting 12 used to connect a second horizontal member 22 to the wooden structural member 2 is connected to a second side surface 2B of the wooden structural member 2. A third metal fitting 13 used to connect a third horizontal member 23 to the wooden structural member 2 is connected to a third side surface 2C of the wooden structural member 2. A fourth metal fitting 14 used to connect a fourth horizontal member 24 to the wooden structural member 2 is connected to the third side surface 2C of the wooden structural member 2. A fifth metal fitting 15 used to connect a fifth horizontal member 25 to the wooden structural member 2 is connected to the third side surface 2C of the wooden structural member 2. A sixth metal fitting 16 used to connect a sixth horizontal member 26 to the wooden structural member 2 is connected to a fourth side surface 2D of the wooden structural member 2. A wooden-structural-member joint rod 17 is vertically inserted through an upper end surface 2E of the wooden structural member 2 to couple the wooden structural member 2 to another wooden structural member 2. A foundation metal fitting 18 is connected to a lower end surface 2F of the wooden structural member 2. The foundation metal fitting 18 connects the foundation to the wooden structural member 2.

As shown in FIG. 2, each metal fitting 10 is fixed to the wooden structural member 2 using bolts 20. Each bolt 20 is inserted into a bolt hole 28 provided in the wooden structural member 2. The wooden structural member 2 includes multiple bolt holes 28. To connect multiple metal fittings 10 to the wooden structural member 2, the bolt holes 28 are arranged so as not to interfere with each other. The processing information generation system 40 will now be described.

### Processing Information Generation System

The processing information generation system 40 generates the hole forming information to assemble the wooden structural member 2 as illustrated in FIGS. 1 to 5.

As shown in FIG. 6, the processing information generation system 40 includes an information acquisition unit 41 and a processing information generation unit 42. A display unit 43 that displays a processing result is connected to the processing information generation unit 42. The processing information generation system 40 includes one or more central processing units (CPUs) or micro-processing units (MPUs). The processing information generation system 40 may include one or more processors that execute various processes in accordance with a computer program (software). The processing information generation system 40 may include a combination of the above-described processors and hardware circuits. Each processor includes a CPU and a memory such as a RAM and ROM. The memory stores program code or instructions configured to cause the CPU to execute processes. The memory, or a computer-readable medium, includes any type of media that are accessible by general-purpose computers and dedicated computers.

The processing information generation system 40 generates the hole forming information for the wooden structural member 2. The processing information generation system 40 generates the hole forming information for the wooden structural member 2 based on the information set by the structural design system 1. The hole forming information includes information related to the number and arrangement of bolt holes 28 in the wooden structural member 2.

### Information Acquisition Unit

The information acquisition unit 41 acquires wooden structural member information, metal fitting information, and fixed position information. Hereinafter, the wooden structural member information, the metal fitting information, and the fixed position information are collectively referred to as wooden structural member-related information. The information acquisition unit 41 acquires the wooden structural member-related information for each of all or some wooden structural members 2 included in the framework structure of a building. In the present embodiment, the wooden structural member-related information is acquired from the structural design system 1.

The wooden structural member information is related to the shape of each wooden structural member 2. The wooden structural member information includes information for the dimensions of the surfaces of the wooden structural member 2, the relationship between the surfaces, and the position of the wooden structural member 2 in the framework structure. For example, the wooden structural member 2 includes the first side surface 2A, the second side surface 2B, the third side surface 2C, which is opposite the first side surface 2A, and the fourth side surface 2D, which is opposite the second side surface 2B. The wooden structural member 2 further includes the upper end surface 2E and the lower end surface 2F. In this case, the wooden structural member information includes the dimensions of the first side surface 2A to the fourth side surface 2D and the arrangement of the first side surface 2A to the fourth side surface 2D. The wooden structural member information may include information related to the orientation of the first side surface 2A relative to the reference direction of a building.

The metal fitting information is related to each metal fitting 10 connected to the wooden structural member 2. The metal fitting information is related to the metal fitting 10 set for the wooden structural member 2 by the structural design system 1. The metal fitting information includes information such as the shape and dimension of the metal fitting 10, the number of metal fitting holes 10A in the metal fitting 10, the position of a metal fitting hole 10A that cannot be used for fixing (hereinafter referred to as an invalid hole position), and the number of bolts required for fixing the metal fitting 10 to the wooden structural member 2 (hereinafter referred to as the required number of bolts). The required number of bolts is set by calculating the strength of connection between the wooden structural member 2 and a horizontal member. The required number of bolts is set by the structural design system 1.

The types of metal fittings 10 used for the wooden structural member 2 are preset. All of the usable metal fittings 10 have a common hole pitch (hereinafter referred to as a common hole pitch). The common hole pitch indicates the interval between two adjacent metal fitting holes 10A in each metal fitting 10. The metal fitting 10 includes metal fitting holes 10A at a pitch of an integer multiple of the common hole pitch. The processing information generation system 40 stores the common hole pitch.

The fixed position information indicates the position at which each metal fitting 10 is fixed to the wooden structural member 2. The position of fixing the metal fitting 10 indicates a position in the height direction from the reference surface of the wooden structural member 2. The reference surface of the wooden structural member 2 is the upper end surface 2E or the lower end surface 2F. The fixed position information is set based on the framework structure of a building. The fixed position information is set by the structural design system 1.

The position of fixing each metal fitting 10 is set in accordance with a positioning rule. According to the positioning rule, the position of fixing the metal fitting 10 is set at a distance of an integral multiple of the reference pitch from the reference surface of the wooden structural member 2. The reference pitch is equal to the common hole pitch. The positioning rule is shared by the structural design system 1 and the processing information generation system 40. This facilitates setting of the bolt holes 28 that do not interfere with each other.

### Processing Information Generation Unit

The processing information generation unit 42 executes a grouping process, a hole candidate setting process, and a selection process. The processing information generation unit 42 may execute a bolt hole type determination process.

### Grouping Process

In the grouping process, the processing information generation unit groups, when metal fittings 10 are arranged on the wooden structural member 2, the metal fittings 10 having overlapping hole positions in the height direction. The grouping is based on the metal fitting information and the fixed position information.

In the grouping process, the processing information generation unit 42 creates a group by repeating a group association process on the metal fittings 10 in the order in which the metal fittings 10 are arranged in the height direction.

In the group association process, the processing information generation unit 42 assigns a metal fitting 10 subject to the grouping process to the group when the position of one of metal fitting holes 10A subject to the grouping process overlaps the position of a metal fitting hole 10A of at least one metal fitting 10 that has already been assigned to the group prior to the metal fitting 10 subject to the grouping process.

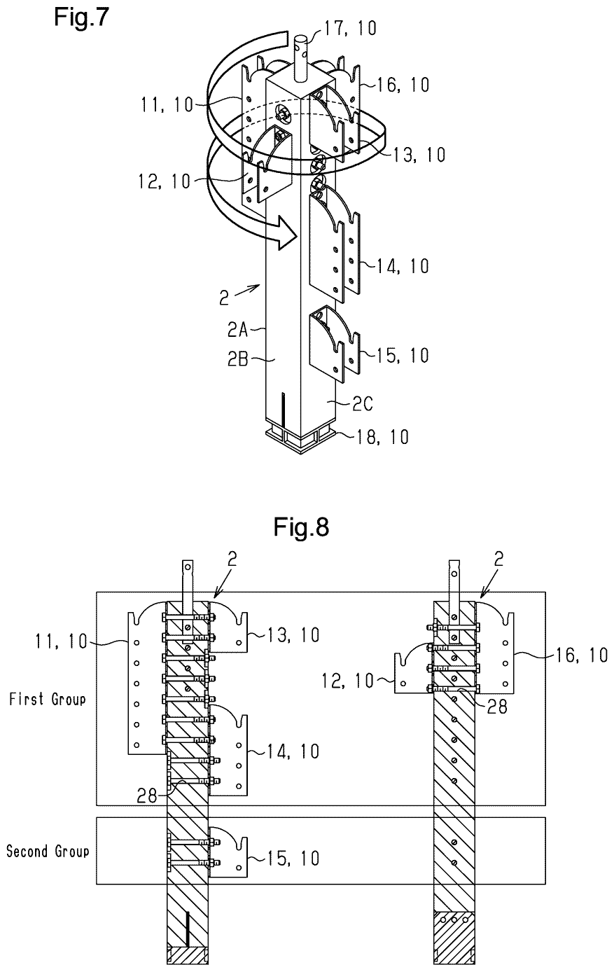

An example of grouping will now be described with reference to FIG. 7. In the present embodiment, the processing information generation unit 42 performs the grouping process on the metal fittings 10 provided on the first side surface 2A to the fourth side surface 2D.

As illustrated in FIG. 7, the processing information generation unit 42 detects the presence or absence of metal fittings 10 in the order of the first side surface 2A, the third side surface 2C, the second side surface 2B, and the fourth side surface 2D of a wooden structural member 2 to be calculated, while advancing downward by a predetermined pitch from the upper end surface 2E relative to that wooden structural member 2. The downward movement by the predetermined pitch is performed after the detection of the first side surface 2A to the fourth side surface 2D is completed. This allows the group association process to be repeated for the metal fittings 10 in the order in which the metal fittings 10 are arranged in the height direction.

Initially, the first group includes one element. Specifically, the metal fitting 10 at the highest position in the wooden structural member 2 is assigned to the first group. For example, the first group initially includes the first metal fitting 11 on the first side surface 2A.

Next, the processing information generation unit 42 executes the group association process. Specifically, the processing information generation unit 42 detects the third metal fitting 13 on the third side surface 2C. It is determined whether the position of one of the holes in the third metal fitting 13 overlaps the position of one of the holes in the first metal fitting 11, which has already been assigned to the group prior to that metal fitting 10 (i.e., the third metal fitting 13). When the position of one of the holes of the third metal fitting 13 overlaps the position of one of the holes of the first metal fitting 11, the third metal fitting 13 is assigned to the first group.

The processing information generation unit 42 repeats the group association process. When failing to detect a metal fitting 10 in four consecutive instances, the processing information generation unit 42 completes the grouping for the first group. Next, the processing information generation unit 42 creates a second group as a new group, and subsequently repeats the group association process.

As shown in FIG. 8, in the present embodiment, the first group includes the first metal fitting 11, the second metal fitting 12, the third metal fitting 13, the fourth metal fitting 14, and the sixth metal fitting 16. The second group includes the fifth metal fitting 15.

After completing the grouping for all the metal fittings 10 in the wooden structural member 2, the processing information generation unit 42 executes the following processes.

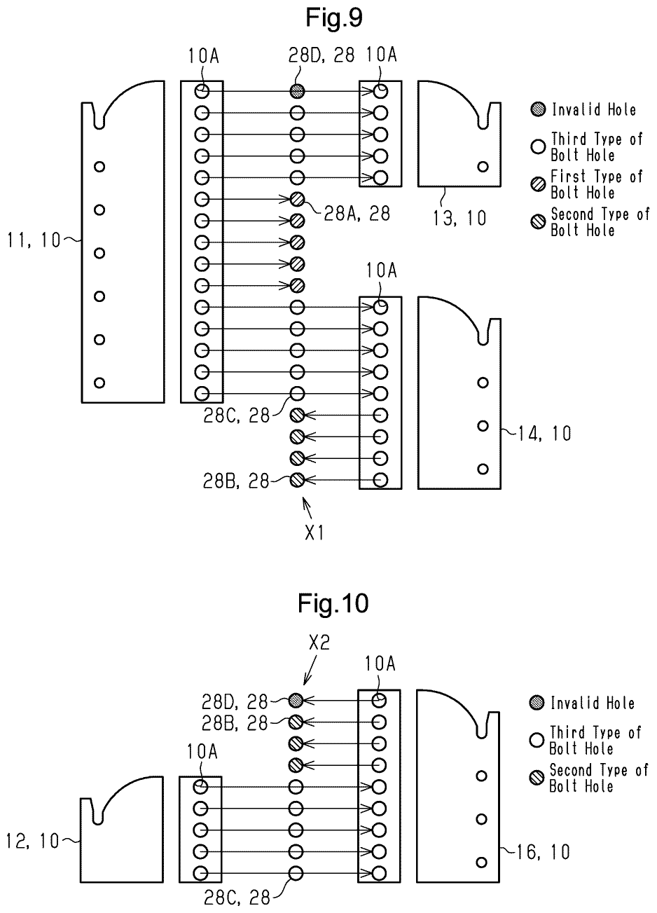

As shown in FIG. 9, in the grouping process, the processing information generation unit 42 classifies ones of the grouped metal fittings 10 arranged on the first side surface 2A and the third side surface 2C into a first subgroup.

As shown in FIG. 10, in the grouping process, the processing information generation unit 42 classifies ones of the grouped metal fittings 10 arranged on the second side surface 2B and the fourth side surface 2D into a second subgroup.

### Hole Candidate Setting Process

The hole candidate setting process will now be described with reference to FIGS. 9 and 10.

In the hole candidate setting process, the processing information generation unit 42 sets, based on the metal fitting information for each metal fitting 10 belonging to the group, bolt hole candidates for fixing the metal fitting 10 belonging to the group. The first group will now be described.

As shown in FIG. 9, the processing information generation unit 42 sets first bolt hole candidates X1 for the first subgroup.

Specifically, the processing information generation unit 42 sets the first bolt hole candidates X1 based on the metal fitting holes 10A in the first metal fitting 11, the metal fitting holes 10A in the third metal fitting 13, and the metal fitting holes 10A in the fourth metal fitting 14. All of the metal fitting holes 10A in the first metal fitting 11, the metal fitting holes 10A in the third metal fitting 13, and the metal fitting holes 10A in the fourth metal fitting 14 are set as the first bolt hole candidates X1. In the height direction, among the metal fitting holes 10A in the third metal fitting 13 and the metal fitting holes 10A in the fourth metal fitting 14, the metal fitting holes 10A at the same heights as the holes in the first metal fitting 11 serve as bolt hole candidates shared between the two metal fittings 10 (i.e., the first metal fitting 11 and either the third metal fitting 13 or the fourth metal fitting 14).

As shown in FIG. 10, the processing information generation unit 42 sets second bolt hole candidates X2 for the second subgroup.

Specifically, the processing information generation unit 42 sets the second bolt hole candidates X2 based on the metal fitting holes 10A in the second metal fitting 12 and the sixth metal fitting 16. All of the metal fitting holes 10A in the second metal fitting 12 and the metal fitting holes 10A in the fourth metal fitting 14 are set as the second bolt hole candidates X2. In the height direction, among the metal fitting holes 10A in the fourth metal fitting 14, the metal fitting holes 10A at the same heights as the holes in the second metal fitting 12 serve as bolt hole candidates shared between the two metal fittings 10 (i.e., the second metal fitting 12 and the fourth metal fitting 14).

Further, in the hole candidate setting process, the processing information generation unit 42 selects bolt hole candidates based on fixing hole information, which is included in the metal fitting information.

The fixing hole information includes information related to a hole that cannot be used as a bolt hole 28 in each metal fitting 10 (hereinafter referred to as an invalid hole 28D). The fixing hole information includes information for the presence or absence of the invalid hole 28D and invalid hole position of the invalid hole 28D in the metal fitting 10. For example, the metal fitting hole 10A at the uppermost position in the metal fitting 10 is set as the invalid hole 28D.

When the invalid hole 28D is included in the fixing hole information, the processing information generation unit 42 excludes the invalid hole 28D from the first bolt hole candidates X1 and the second bolt hole candidates X2.

### Bolt Hole Type Determination Process

In the bolt hole type determination process, the processing information generation unit 42 sets the type of bolt hole 28 for each bolt hole candidate based on the positional relationship between the metal fittings 10.

The type of bolt hole 28 may be determined after the selection process. In the bolt hole type determination process, the processing information generation unit 42 sets the type of bolt hole 28 for each of the selected bolt holes 28 based on the arrangement of the bolt holes 28 relative to each metal fitting 10.

The type of bolt hole 28 is classified into three types depending on the presence or absence of a counterbore 29 that accommodates a bolt head. A first type of bolt hole 28A has the counterbore 29 at the right end thereof as viewed in a reference direction. A second type of bolt hole 28B has the counterbore 29 at the left end thereof as viewed in the reference direction. A third type of bolt hole 28C has no counterbore 29 at either end.

The reference direction is preset. The reference direction is defined for each of the first and second subgroups. In the present embodiment, the reference direction of the first subgroup faces the A-A cross-section in FIG. 2. The reference direction of the second subgroup faces the cross-section B-B in FIG. 2.

When the surface of the bolt hole 28 where the metal fitting 10 is disposed includes an opening end, the counterbore 29 is not provided on that surface. When the surface of the bolt hole 28 where the metal fitting 10 is not disposed includes an opening end, the counterbore 29 is provided on that surface.

In the bolt hole type determination process, the processing information generation unit 42 determines the type of bolt hole 28 based on the positional relationship with the metal fitting 10.

### Selection Process

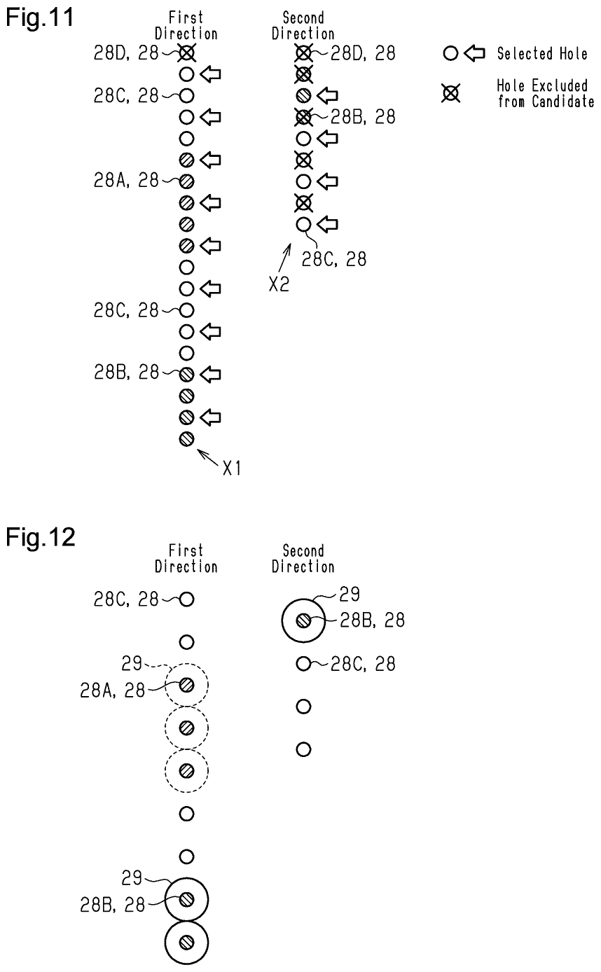

The selection process will now be described with reference to FIGS. 11 and 12. FIGS. 11 and 12 each illustrate a first direction oriented from the first side surface 2A toward the third side surface 2C. FIGS. 11 and 12 each illustrate a second direction oriented from the second side surface 2B toward the fourth side surface 2D. FIG. 12 illustrates a circle surrounding a bolt hole 28 that indicates a counterbore 29. The counterbore 29 shown by the solid line indicates the counterbore 29 on the front side of the wooden structural member 2 as viewed in the first or second direction. The counterbore 29 shown by the broken line indicates the counterbore 29 on the rear side of the wooden structural member 2 as viewed in the first or second direction.

In the selection process, the processing information generation unit 42 selects a bolt hole 28 that satisfies a predetermined condition for a metal fitting 10 from the bolt hole candidates.

Specifically, in the selection process, the processing information generation unit 42 selects a bolt hole 28 from each of the first bolt hole candidates X1 and the second bolt hole candidates X2 so as to satisfy a first condition and a second condition. The first condition is that the bolt hole 28 selected from the first bolt hole candidate X1 and the bolt hole 28 selected from the second bolt hole candidate X2 do not interfere with each other. The second condition is that a fixing condition for a metal fitting 10 is satisfied. The fixing condition for the metal fitting 10 is that the number of bolt holes 28 satisfies the required number of bolts.

The processing information generation unit 42 executes a first pattern selection process. Specifically, the processing information generation unit 42 selects a candidate for a bolt hole 28 so as to satisfy the fixing condition for the metal fitting 10 from the first bolt hole candidates X1. For example, when the uppermost one in the first metal fitting 11 is the invalid hole 28D, the processing information generation unit 42 excludes the uppermost one from the first bolt hole candidates X1, sets the second hole from the top as a start hole, and selects every other bolt hole 28. Then, the processing information generation unit 42 determines whether all the metal fittings 10 belonging to the first subgroup satisfy the fixing condition. Specifically, the processing information generation unit 42 determines that the fixing condition is satisfied when the number of selected bolt holes 28 in each of the metal fittings 10 in the first subgroup is greater than or equal to the required number of bolts for that metal fitting 10.

Next, the processing information generation unit 42 selects a bolt hole 28 from the second bolt hole candidates X1 such that the bolt hole 28 selected from the first bolt hole candidates X1 and the bolt hole 28 selected from the second bolt hole candidates X2 do not interfere with each other. Specifically, the processing information generation unit 42 excludes, from the second bolt hole candidates X2, the bolt hole 28 at the same height as the bolt hole 28 selected from the first bolt hole candidates X1. Then, the processing information generation unit 42 selects, as the bolt holes 28 to be used, the remaining bolt holes 28 that were not excluded. Then, the processing information generation unit 42 determines whether all the metal fittings 10 belonging to the second subgroup satisfy the fixing condition. Specifically, the processing information generation unit 42 determines that the fixing condition is satisfied when the number of selected bolt holes 28 in each of the metal fittings 10 in the second subgroup is greater than or equal to the required number of bolts for that metal fitting 10. When the fixed condition is satisfied, the processing information generation unit 42 completes the process.

When the fixing condition is not satisfied, the processing information generation unit 42 resets the bolt hole 28 selected from the first bolt hole candidates X1 and the bolt hole 28 selected from the second bolt hole candidates X2.

Then, the processing information generation unit 42 executes a second pattern selection process as follows. Specifically, the processing information generation unit 42 first selects a bolt hole 28 from the second bolt hole candidates X2. The processing information generation unit 42 determines whether all the metal fittings 10 belonging to the second subgroup satisfy the fixing condition. Next, the processing information generation unit 42 selects the bolt hole 28 from the first bolt hole candidates X1 so as not to interfere with the bolt hole 28 selected from the second bolt hole candidate X2. The processing information generation unit 42 determines whether all the metal fittings 10 belonging to the first subgroup satisfy the fixing condition.

In the second pattern selection process, when determining that the fixing condition is satisfied for all the metal fittings 10, the processing information generation unit 42 completes the process. In the second pattern selection process, if even one of the metal fittings 10 fails to satisfy the fixing condition, the processing information generation unit 42 changes the condition. For example, the processing information generation unit 42 executes the first pattern selection process to set the second metal fitting hole 10A from the top as the start hole for the selection and set the third metal fitting hole 10A from the top as the start hole for the selection in the next process. Then, the processing information generation unit 42 executes the first pattern selection process under the changed condition. When the fixed condition is not satisfied in the first pattern selection process, the processing information generation unit 42 executes a second pattern selection process. The processing information generation unit 42 selects a bolt hole 28 that satisfies the fixing condition by repeating the first pattern selection process, the second pattern selection process, and the process that changes the start hole. The maximum number of times MAX of the start hole can be changed is preset. When the process that changes the start hole is performed up to the maximum number MAX and the fixing condition still cannot be satisfied for one or more of the metal fittings 10, the processing information generation unit 42 indicates that no selection could be made on the display unit 43 and ends the processing.

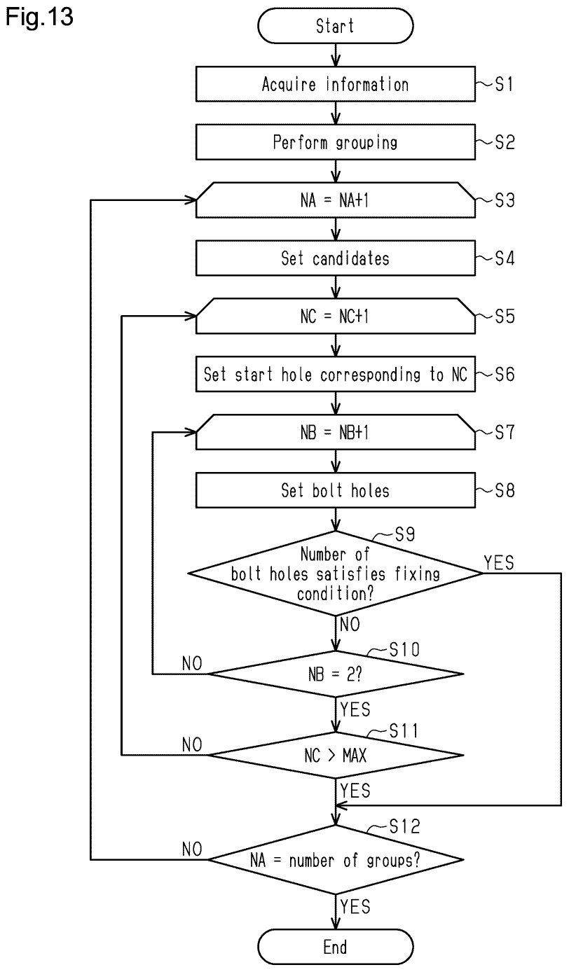

The processing executed by the processing information generation system 40 will now be described with reference to FIG. 13. The processing is executed for each of the wooden structural members 2 of a building.

In the processing, the value of NA indicates the ordinal number of a group of the metal fittings 10. The initial value of NA is 0. When NA is 1, it indicates the first group. When NA is 2, it indicates the second group. NB indicates the ordinal number of each of the pattern selection processes. The initial value of NB is 0. When NB is 1, it indicates the first pattern selection process. When NB is 2, it indicates the second pattern selection process.

NC indicates the number of changes in the start hole. The initial value of NC is −1. When NC is 1, it indicates that the start hole will be changed once.

In the first step S1, the information acquisition unit 41 acquires the wooden structural member information, the metal fitting information, and the fixed position information for a wooden structural member 2 to be processed.

In the second step S2, the processing information generation unit 42 executes the grouping process on the wooden structural member 2 to be processed.

In the third step S3, the number NA is incremented by one. When NA is 1, the first group is to be processed. When NA is 2, the second group is to be processed. That is, the process that selects a bolt hole 28 is executed for each group.

In the fourth step S4, the processing information generation unit 42 executes the hole candidate setting process as described above. In the fifth step S5, the number NC is incremented by one.

In the sixth step S6, the processing information generation unit 42 sets a start hole corresponding to NC. When NC is 0, the start hole is not changed. When NC is 1, the processing information generation unit 42 changes the position of the start hole to the position one level lower.

In the seventh step S7, the number NB is incremented by one. When NB is 1, the execution of the first pattern selection process is prepared. When NB is 2, the execution of the second pattern selection process is prepared.

In the eighth step S8, the processing information generation unit 42 selects bolt holes 28 by executing the process prepared in the seventh step S7.

In the ninth step S9, the processing information generation unit 42 determines, for each metal fitting 10, whether the number of the selected bolt holes 28 satisfies the fixing condition. When all of the metal fittings 10 satisfy the fixing condition, it is determined that the fixing condition is satisfied. In this case, the processing information generation unit 42 executes the process of the twelfth step S12. If even one of the metal fittings 10 does not satisfy the fixing condition, it is determined that the fixing condition is not satisfied. In this case, the processing information generation unit 42 executes the process of the next step, i.e., tenth step S10.

In the tenth step S10, when NB is 2, the processing information generation unit 42 executes the process of the next step, i.e., eleventh step S11. When NB is not 2, the processing information generation unit 42 executes the process of the seventh step S7.

In the eleventh step S11, it is determined whether NC is greater than the maximum number of times MAX. When NC is not greater than the maximum number of times MAX, the processing information generation unit 42 executes the process of the fifth step S5. Since the value of NC is incremented by one in step S5, the condition for the start hole is changed. When NC is greater than the maximum number of times MAX, the processing information generation unit 42 executes the next step, i.e., twelfth step $12, and outputs a message indicating that no bolt hole 28 can be selected for the group to the display unit 43.

In the twelfth step S12, it is determined whether NA is equal to the number of groups. When NC is equal to the number of groups, the processing information generation unit 42 ends the processing. At the end of the processing, the bolt holes 28 are selected for each group that has been set for the wooden structural member 2.

### Operation of the Present Embodiment

When a larger number of metal fittings 10 are connected to the wooden structural member 2, a larger number of bolt holes 28 are used to fix the metal fittings 10. This makes it difficult to set the bolt holes 28 such that the bolt holes 28 do not interfere with each other and the fixing conditions are satisfied. When the bolt holes 28 are sequentially selected for each metal fitting 10 without any grouping and the bolt holes 28 that interfere with each other are found during the selection, the selection may need to be restarted.

In the processing information generation system 40 of the present embodiment, the processing information generation unit 42 executes the grouping process. In the grouping process, when metal fittings 10 are arranged on the wooden structural member 2, the metal fittings 10 having overlapping hole positions are grouped in the height direction. The grouping is based on the metal fitting information and the fixed position information. Grouping the metal fittings 10 allows the selection of bolt holes 28 such that mutual interference is avoided within a group of bolt holes 28 that may otherwise interfere with each other. This reduces the likelihood of overlooking interfering bolt holes 28 and thus contributes to improved efficiency in selecting the bolt holes 28.

Further, the positions of bolt holes 28 are determined for each group. This minimizes the need to reset hole positions. In this manner, the efficiency of generating processing data for the wooden structural member 2 is enhanced.

### Advantages of the Present Embodiment

(1) In the processing information generation system 40, the processing information generation unit 42 executes the grouping process. In the grouping process, when metal fittings 10 are arranged on the wooden structural member 2, the metal fittings 10 having overlapping hole positions are grouped in the height direction. The grouping is based on the metal fitting information and the fixed position information.

In this configuration, the grouping process is executed to group the metal fittings 10 having overlapping hole positions. This allows the positions of the bolt holes 28 to be determined for each group and thus minimizes the need to reset the positions of the bolt holes 28. In this manner, the efficiency of generating processing data for the wooden structural member 2 is enhanced.
(2) In the grouping process, the processing information generation unit 42 classifies ones of the grouped metal fittings 10 arranged on the first side surface 2A and the third side surface 2C into the first subgroup. The processing information generation unit 42 classifies ones of the grouped metal fittings 10 arranged on the second side surface 2B and the fourth side surface 2D into the second subgroup. In the hole candidate setting process, the first bolt hole candidates X1 are set for the first subgroup and the second bolt hole candidates X2 are set for the second subgroup.

In this configuration, each of the first and second subgroups is formed by grouping the metal fittings 10 located on the opposite sides of the wooden structural member 2. Further, candidates for the bolt holes 28 are set independently for each of the first and second subgroups. This reduces the number of selectable bolt holes 28, thereby improving calculation efficiency.
(3) In the grouping process, the processing information generation unit 42 creates a group by repeating the group association process on the metal fittings 10 in the order in which the metal fittings 10 are arranged in the height direction. In the group association process, a metal fitting 10 subject to the grouping process is assigned to the group when the position of one of metal fitting holes 10A of the metal fitting 10 subject to the grouping process overlaps the position of a metal fitting hole 10A of at least one of the metal fittings 10 that have already been assigned to the group prior to the metal fitting 10 subject to the grouping process.

This configuration prevents a metal fitting 10 that should be grouped from being excluded from that group, thereby properly grouping metal fittings 10.
(4) In the bolt hole type determination process, the processing information generation unit 42 sets the type of bolt hole 28 for each bolt hole candidate or each selected bolt hole 28 based on the positional relationship between the metal fittings 10. This configuration allows the type of bolt hole 28 to be set.
(5) In the hole candidate setting process, the processing information generation unit 42 selects bolt hole candidates based on the fixing hole information, which is included in the metal fitting information. This configuration allows for selection of bolt hole candidates suitable for each metal fitting 10.

### Modifications

The above-described embodiment exemplifies, without any intention to limit, an applicable form of the processing information generation system 40. The processing information generation system 40 is applicable to forms different from the example described in the above-described embodiment. For example, the structures of the above-described embodiment may be replaced, changed, or omitted in part or include additional elements. Modifications to the embodiment will now be described.

The technique of the present disclosure may be implemented as a program executed by a computer. The processing information generation program causes the computer to generate hole forming information for the wooden structural member 2. The processing information generation program includes an information acquisition step and a processing information generation step.

The information acquisition step causes the computer to acquire the wooden structural member information, the metal fitting information for the metal fittings 10 connected to the wooden structural member 2, and the fixed position information indicating the position of fixing each metal fitting 10 to the wooden structural member 2.

The processing information generation step causes the computer to execute the grouping process, the hole candidate setting process, and the selection process.

The grouping process causes the computer to group, when metal fittings 10 are arranged on the wooden structural member 2, the metal fittings 10 having overlapping hole positions in the height direction. The grouping is based on the metal fitting information and the fixed position information.

The hole candidate setting process causes the computer to set, based on the metal fitting information for each metal fitting 10 belonging to the group, bolt hole candidates for fixing the metal fitting 10 belonging to the group.

The selection process causes the computer to select the bolt hole 28 satisfying the fixing condition for the metal fitting 10 from the bolt hole candidates.

In this configuration, the grouping process is executed to group metal fittings 10 having overlapping hole positions. This allows the hole positions to be determined for each group and thus minimizes the need to reset hole positions. In this manner, the efficiency of generating processing data for the wooden structural member 2 is enhanced.

This specification further discloses the following techniques.
[Clause 1] A processing information generation system generates hole forming information for a wooden structural member, the processing information generation system including an information acquisition unit and a processing information generation unit.

The information acquisition unit acquires wooden structural member information, metal fitting information for metal fittings connected to the wooden structural member, and fixed position information indicating a position at which each of the metal fittings is fixed to the wooden structural member, and
the processing information generation unit includes:
   a grouping process in which, when the metal fittings are arranged on the wooden structural member, ones of the metal fittings having overlapping hole positions are grouped in a height direction, the grouping being based on the metal fitting information and the fixed position information;
   a hole candidate setting process that sets, based on the metal fitting information for each of the metal fittings that belong to the group, bolt hole candidates for fixing the metal fittings that belong to the group; and
   a selection process that selects a bolt hole that satisfies a fixing condition for the metal fittings from the bolt hole candidates.
.
[Clause 2] The processing information generation system according to clause 1,
where the wooden structural member includes a first side surface, a second side surface, a third side surface opposite the first side surface, and a fourth side surface opposite the second side surface.

The processing information generation unit performs:
in the grouping process, classifying ones of the grouped metal fittings arranged on the first side surface and the third side surface into a first subgroup and classifying ones of the grouped metal fittings arranged on the second side surface and the fourth side surface into a second subgroup;
in the hole candidate setting process, setting first bolt hole candidates for the first subgroup and second bolt hole candidates for the second subgroup; and
in the selection process, selecting a bolt hole from each of the first bolt hole candidates and the second bolt hole candidates such that a bolt hole selected from the first bolt hole candidates and a bolt hole selected from the second bolt hole candidates do not interfere with each other and the fixing condition for the metal fittings is satisfied.
[Clause 3] The processing information generation system according to clause 1, where
in the grouping process, the processing information generation unit creates a group by repeating a group association process on the metal fittings in an order in which the metal fittings are arranged in the height direction, and
in the group association process, the processing information generation unit assigns a metal fitting subject to the grouping process to the group when a position of one of metal fitting holes of the metal fitting subject to the grouping process overlaps a position of a metal fitting hole of at least one of the metal fittings that have already been assigned to the group prior to the metal fitting subject to the grouping process.
[Clause 4] The processing information generation system according to clause 1, where
the processing information generation unit further executes a bolt hole type determination process, and in the bolt hole type determination process, and
the processing information generation unit sets a type of bolt hole for each of the bolt hole candidates or each of the selected bolt holes based on a positional relationship between the metal fittings.
[Clause 5] The processing information generation system according to clause 4, where
the wooden structural member includes a first side surface, a second side surface, a third side surface opposite the first side surface, and a fourth side surface opposite the second side surface.

The processing information generation unit performs:
in the grouping process, classifying ones of the grouped metal fittings arranged on the first side surface and the third side surface into a first subgroup and classifying ones of the grouped metal fittings arranged on the second side surface and the fourth side surface into a second subgroup;
in the hole candidate setting process, setting first bolt hole candidates for the first subgroup and second bolt hole candidates for the second subgroup; and
in the selection process, selecting a bolt hole from each of the first bolt hole candidates and the second bolt hole candidates such that a bolt hole selected from the first bolt hole candidates and a bolt hole selected from the second bolt hole candidates do not interfere with each other and the fixing condition for the metal fittings is satisfied.
[Clause 6] The processing information generation system according to clause 5, where
in the grouping process, the processing information generation unit creates a group by repeating a group association process on the metal fittings in an order in which the metal fittings are arranged in the height direction; and
in the group association process, the processing information generation unit assigns a metal fitting subject to the grouping process to the group when a position of one of metal fitting holes of the metal fitting subject to the grouping process overlaps a position of a metal fitting hole of at least one of the metal fittings that have already been assigned to the group prior to the metal fitting subject to the grouping process.
[Clause 7] In the processing information generation system according to any one of clauses 1 to 6, where, in the hole candidate setting process, the processing information generation unit selects the bolt hole candidates based on fixing hole information, the fixing hole information being included in the metal fitting information.
[Clause 8] A processing information generation program that causes a computer to generate hole forming information for a wooden structural member, the processing information generation program including an information acquisition step and a processing information generation step, where
the information acquisition step causes the computer to acquire wooden structural member information, metal fitting information for metal fittings connected to the wooden structural member, and fixed position information indicating a position at which each of the metal fittings is fixed to the wooden structural member, and
the processing information generation step causes the computer to execute:
   a grouping process in which, when the metal fittings are arranged on the wooden structural member, ones of the metal fittings having overlapping hole positions are grouped in a height direction, the grouping being based on the metal fitting information and the fixed position information;
   a hole candidate setting process that sets, based on the metal fitting information for each of the metal fittings that belong to the group, bolt hole candidates for fixing the metal fittings that belong to the group; and
   a selection process that selects a bolt hole that satisfies a fixing condition for the metal fittings from the bolt hole candidates.

### REFERENCE SIGNS LIST

1) Structural Design System; 2) Wooden Structural Member; 10) Metal Fitting; 10A) Metal Fitting Hole; 17) Wooden-Structural-Member Joint Rod; 18) Foundation Metal Fitting; 20) Bolt; 28) Bolt Hole; 28D) Invalid Hole; 29) Counterbore; 40) Processing Information Generation System; 41) Information Acquisition Unit; 42) Processing Information Generation Unit; 43) Display Unit.

1. A processing information generation system for generating hole forming information for a wooden structural member, the processing information generation system comprising:
an information acquisition unit; and
a processing information generation unit, wherein
the information acquisition unit acquires wooden structural member information, metal fitting information for metal fittings connected to the wooden structural member, and fixed position information indicating a position at which each of the metal fittings is fixed to the wooden structural member, and
the processing information generation unit includes:
a grouping process in which, when the metal fittings are arranged on the wooden structural member, ones of the metal fittings having overlapping hole positions are grouped in a height direction, the grouping being based on the metal fitting information and the fixed position information;
a hole candidate setting process that sets, based on the metal fitting information for each of the metal fittings that belong to the group, bolt hole candidates for fixing the metal fittings that belong to the group; and
a selection process that selects a bolt hole that satisfies a fixing condition for the metal fittings from the bolt hole candidates.

2. The processing information generation system according to claim 1, wherein
the wooden structural member includes a first side surface, a second side surface, a third side surface opposite the first side surface, and a fourth side surface opposite the second side surface, and
the processing information generation unit performs:
in the grouping process, classifying ones of the grouped metal fittings arranged on the first side surface and the third side surface into a first subgroup and classifying ones of the grouped metal fittings arranged on the second side surface and the fourth side surface into a second subgroup;
in the hole candidate setting process, setting first bolt hole candidates for the first subgroup and second bolt hole candidates for the second subgroup; and
in the selection process, selecting a bolt hole from each of the first bolt hole candidates and the second bolt hole candidates such that a bolt hole selected from the first bolt hole candidates and a bolt hole selected from the second bolt hole candidates do not interfere with each other and the fixing condition for the metal fittings is satisfied.

3. The processing information generation system according to claim 1, wherein the processing information generation unit performs:
in the grouping process, creating a group by repeating a group association process on the metal fittings in an order in which the metal fittings are arranged in the height direction; and
in the group association process, assigning a metal fitting subject to the grouping process to the group when a position of one of metal fitting holes of the metal fitting subject to the grouping process overlaps a position of a metal fitting hole of at least one of the metal fittings that have already been assigned to the group prior to the metal fitting subject to the grouping process.

4. The processing information generation system according to claim 1, wherein
the processing information generation unit further executes a bolt hole type determination process, and
in the bolt hole type determination process, the processing information generation unit sets a type of bolt hole for each of the bolt hole candidates or each of the selected bolt holes based on a positional relationship between the metal fittings.

5. The processing information generation system according to claim 4, wherein
the wooden structural member includes a first side surface, a second side surface, a third side surface opposite the first side surface, and a fourth side surface opposite the second side surface, and
the processing information generation unit performs:
in the grouping process, classifying ones of the grouped metal fittings arranged on the first side surface and the third side surface into a first subgroup and classifying ones of the grouped metal fittings arranged on the second side surface and the fourth side surface into a second subgroup;
in the hole candidate setting process, setting first bolt hole candidates for the first subgroup and second bolt hole candidates for the second subgroup; and
in the selection process, selecting a bolt hole from each of the first bolt hole candidates and the second bolt hole candidates such that a bolt hole selected from the first bolt hole candidates and a bolt hole selected from the second bolt hole candidates do not interfere with each other and the fixing condition for the metal fittings is satisfied.

6. The processing information generation system according to claim 5, wherein the processing information generation unit performs:
in the grouping process, creating a group by repeating a group association process on the metal fittings in an order in which the metal fittings are arranged in the height direction; and
in the group association process, assigning a metal fitting subject to the grouping process to the group when a position of one of metal fitting holes of the metal fitting subject to the grouping process overlaps a position of a metal fitting hole of at least one of the metal fittings that have already been assigned to the group prior to the metal fitting subject to the grouping process.

7. The processing information generation system according to claim 1, wherein
in the hole candidate setting process, the processing information generation unit selects the bolt hole candidates based on fixing hole information, the fixing hole information being included in the metal fitting information.

8. A processing information generation program that causes a computer to generate hole forming information for a wooden structural member, the processing information generation program comprising:
an information acquisition step; and
a processing information generation step, wherein
the information acquisition step causes the computer to acquire wooden structural member information, metal fitting information for metal fittings connected to the wooden structural member, and fixed position information indicating a position at which each of the metal fittings is fixed to the wooden structural member, and
the processing information generation step causes the computer to execute:
a grouping process in which, when the metal fittings are arranged on the wooden structural member, ones of the metal fittings having overlapping hole positions are grouped in a height direction, the grouping being based on the metal fitting information and the fixed position information;
a hole candidate setting process that sets, based on the metal fitting information for each of the metal fittings that belong to the group, bolt hole candidates for fixing the metal fittings that belong to the group; and
a selection process that selects a bolt hole that satisfies a fixing condition for the metal fittings from the bolt hole candidates.
